(19) United States
(12) Patent Application Publication
(10) Pub. No.: US 2012/0152320 A1
(43) Pub. Date: Jun. 21, 2012

(54) SOLAR PANEL STRUCTURE AND CORRESPONDING SOLAR PANEL

(75) Inventor: Jorge Miguel Aguglia, Lecce (IT)

(73) Assignee: S.I.E.M. S.R.L, Lecce (IT)

(21) Appl. No.: 13/318,975

(22) PCT Filed: May 5, 2010
(86) PCT No.: PCT/IB10/51968

§ 371 Date: Mar. 6, 2012

(30) Foreign Application Priority Data
May 6, 2009 (IT) TO2009A000363

(51) Int. Cl. H01L 31/058; H01L 31/18; B21D 53/02; F24J 2/04

(52) U.S. Cl. 136/248; 126/634; 29/890.033

(57) ABSTRACT

A basic frame for a solar panel having a container for a liquid, which container is arranged to constitute a thermal solar panel that can be combined with a photovoltaic solar panel having a plurality of cells, wherein the frame is an extruded piece of predetermined length having at least one first channel arranged for inletting a liquid and one second channel arranged for outletting the liquid. The invention also relates to a hybrid solar panel including the basic frame and to a method of manufacturing the solar panel.

### TECHNICAL FIELD

The present invention generally relates to a solar panel structure and to the solar panel obtained by using the structure.

More particularly the present invention relates to a basic frame configured for supporting a photovoltaic solar panel (photovoltaic panel) and forming a thermal solar panel (thermal panel) coupled with the photovoltaic panel.

### PRIOR ART

Panels arranged to convert solar radiation into thermal energy (thermal panels) and electric energy (photovoltaic panels) are well known. In particular, hybrid solar panels (hybrid panels) are known, in which a thermal panel is coupled with a photovoltaic panel.

For instance, publication US_{—}2004/0025931_A1, in the name of the applicant, discloses a hybrid panel in which a photovoltaic panel comprising a plurality of photovoltaic cells and arranged to be directly exposed to solar radiation is coupled, by means of a heat conducting plate, to a container configured for containing water or a similar liquid and forming, in association with the conducting plate, the thermal panel.

The prior art thermal panel is made up of the conducting plate and the container, both made of steel, and internally includes a plurality of partitioning elements, preferably made of steel, arranged to create a preferential path for water used to accumulate thermal energy.

In accordance with such a prior art, the plate and the container are welded or glued at the respective edges, and the partitioning elements are fastened to the plate and the container in equivalent manner.

The Applicant, while realising that the prior art hybrid panel allows improving the overall efficiency of the photovoltaic panel, has detected some limits and problems making the manufacture of such kind of panel difficult and expensive.

First, the Applicant has realised that, since the thermal panel is subjected to internal pressures of at least 2 or 3 bars, fastening the different components (plate, container, partitioning elements) is particularly critical and hence such as to entail high manufacturing times and costs.

The Applicant has further realised that, in use, the thermal panel, and especially the plate and the container, undergo deformations due to the water pressure, which deformations may consequently cause, in some cases, irreparable failures in the cells of the photovoltaic panel.

The Applicant has moreover realised that the prior art panel, in case of different power requirements, must be manufactured with sizes that are different for the different cases in order to cope with the respective market demands, and thus it is scarcely flexible.

In summary, the Applicant has realised that the prior art hybrid panels manufactured in manners similar to those described above suffer from the problems, mutually related, of high manufacturing difficulty, risk of failures and scarce flexibility.

### DESCRIPTION OF THE INVENTION

It is an object of the present invention to solve the problems of the prior art.

The object is achieved by the solar panel structure as claimed herein.

The present invention also concerns a solar panel having the structure according to the invention.

The claims are integral part of the technical teaching provided herein in respect of the invention.

In accordance with a feature of a preferred embodiment of the present invention, the basic frame for a solar panel is obtained by an extrusion process and constitutes a thermal solar panel that can be associated with a photovoltaic solar panel in order to form a hybrid solar panel.

In accordance with another feature of the present invention, the basic frame includes at least one inlet channel and one outlet channel for a cooling liquid used in the thermal solar panel.

In accordance with a further feature of the present invention, the hybrid solar panel obtained by means of the basic frame according to the invention constitutes a modular panel that can be connected side by side with further modular panels through coupling means that are formed in or can be applied to the basic frame itself.

### BRIEF DESCRIPTION OF THE FIGURES

The above and other features and advantages of the present invention will become apparent from the following description of preferred embodiments, made by way of non limiting example with reference to the accompanying drawings, in which elements identified by a same or similar numerical reference denote elements having the same or similar function and construction, and in which:

FIG. 1a is an overall view, conventionally in front perspective, of a detail of a hybrid panel made in accordance with a first embodiment of the present invention;

FIG. 1b is an overall view, conventionally in front perspective, of a detail of a hybrid panel made in accordance with a second embodiment of the present invention;

FIG. 2a is a cross-sectional view of a pair of structural members to be used for making hybrid panels in accordance with the first embodiment of the present invention, where some constructional details are highlighted;

FIG. 2b is a cross-sectional view of a pair of structural members to be used for making hybrid panels in accordance with the second embodiment of the present invention, where some constructional details are highlighted;

FIG. 3 is a view, conventionally in rear perspective, of constructional members associated with the hybrid panel according to the invention;

FIG. 4 schematically shows the behaviour of the liquid flow inside the hybrid panel; and

FIG. 5 shows an exemplary embodiment of electrical connections for the hybrid panel according to the invention.

### DESCRIPTION OF A PREFERRED EMBODIMENT

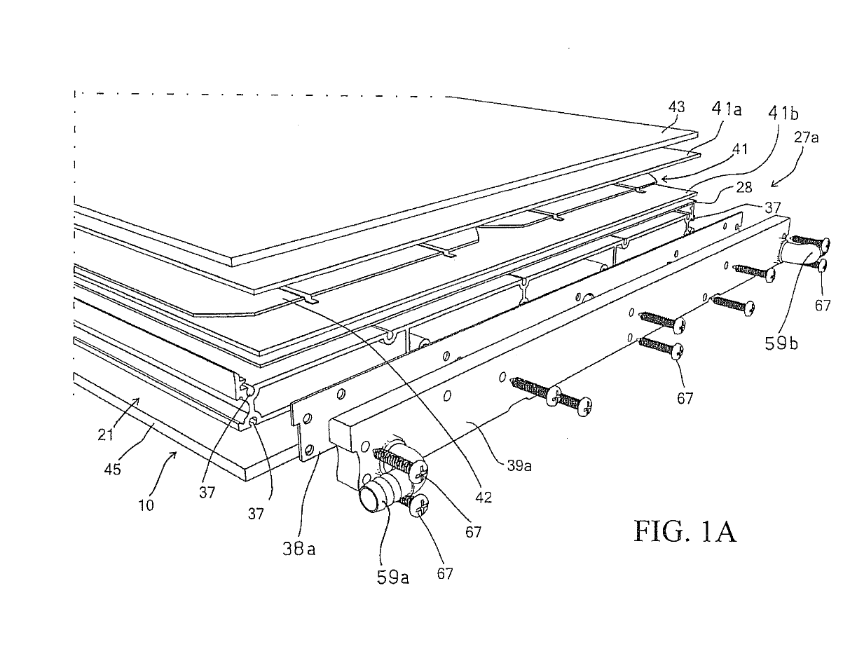

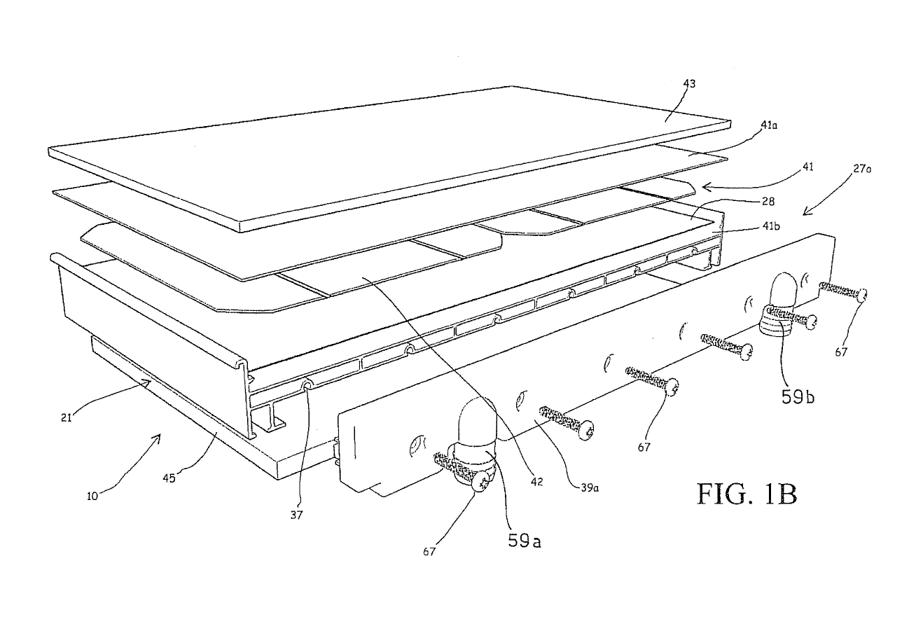

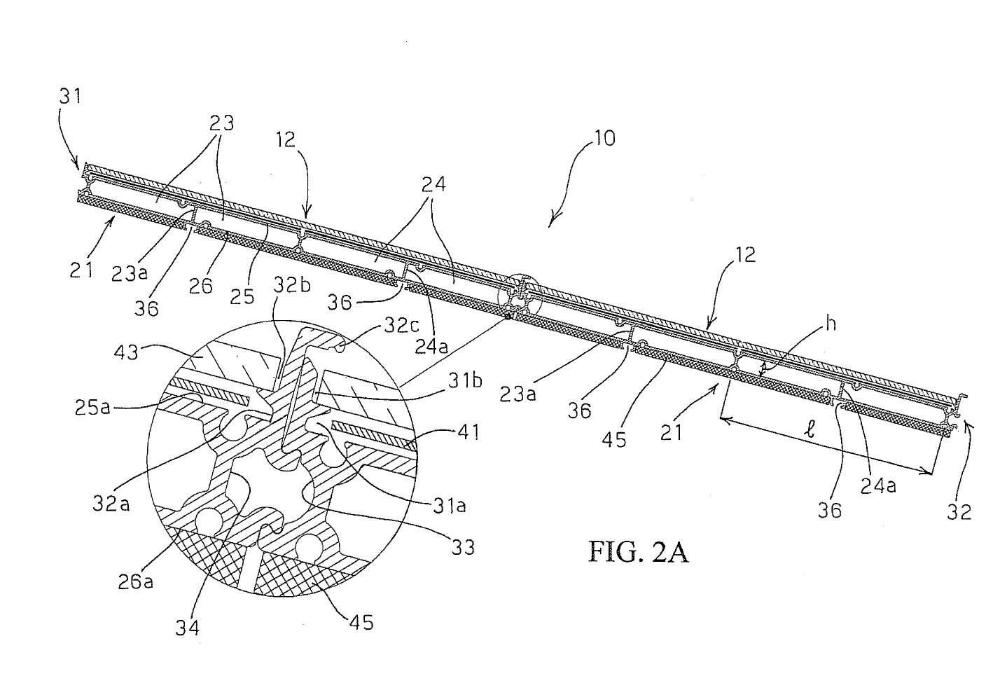

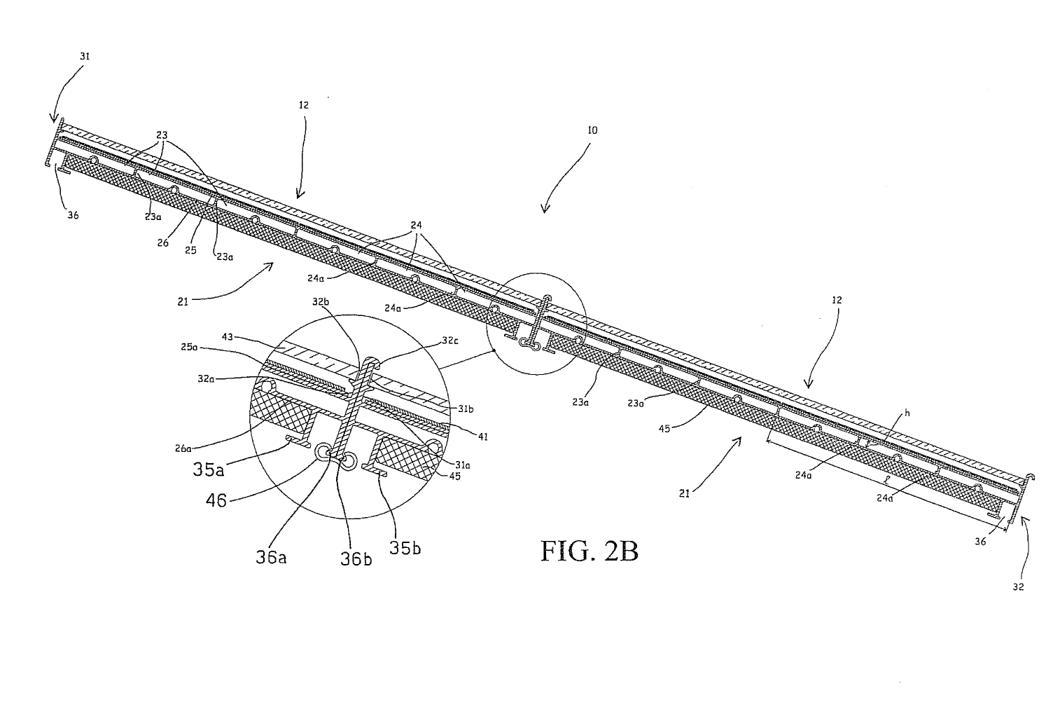

Referring to FIG. 1a or 1b, a solar panel 10 according to the present invention, for instance a hybrid solar panel, comprises one or more modules 12 (FIGS. 1a, 1b, 2a, 2b) of predetermined length.

Each module 12, in the different embodiments, includes a basic frame 21, a photovoltaic panel 41 having a plurality of cells 42, a protective component or panel 43 and, preferably, one or more thermally insulating components or panels 45.

Photovoltaic panel 41, as it will be disclosed in detail below, is fastened to a first face, or upper face, 25a of basic frame 21.

Thermally insulating panel(s) 45, for instance in accordance with a first embodiment shown in FIGS. 1a and 2a, is (are) fastened in known manner to a second face, or lower face, 26a of basic frame 21.

In accordance with a second embodiment shown in FIGS. 1b and 2b, basic frame 21 includes, on opposite longitudinal edges 31 and 32, respective retaining fins 35a and 35b, for instance shaped as an inverted T, configured for receiving thermally insulating panel(s) 45.

In the different embodiments, basic frame 21 is arranged to form both a bearing structure and a modular thermal panel. Preferably, basic frame or thermal panel 21 is made of aluminium alloy, for instance a 6060 alloy resisting to high temperatures, and is obtained by an extrusion process whereby it does not require any welding between possible components of thermal panel 21 itself.

Of course, in accordance with further embodiments, basic frame 21 can be obtained by an extrusion process from other materials, e.g. plastic materials with high thermal and mechanical resistance, without thereby departing from the scope of what described and claimed.

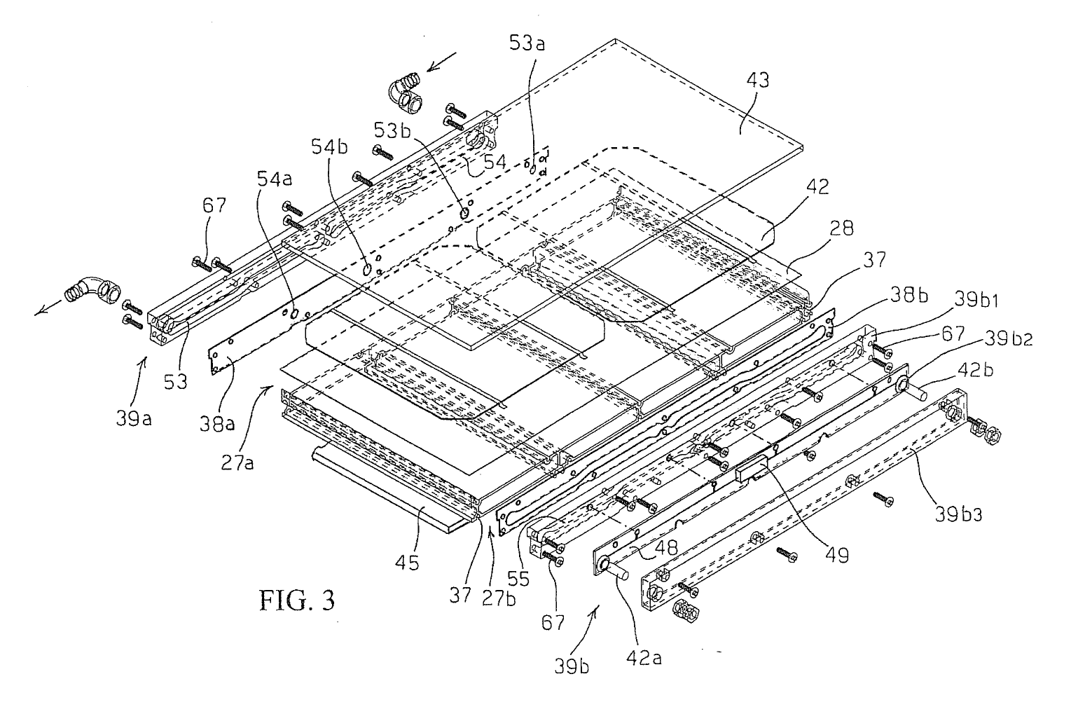

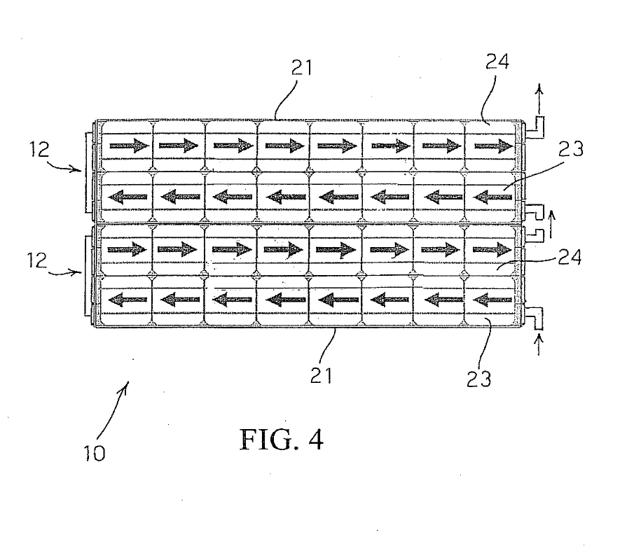

Basic frame or thermal panel 21 (FIGS. 1a, 1b, 2a, 2b, 3, 4) includes a first channel 23, for instance for inletting a liquid such as water, to which reference is made hereinafter for easiness of description, and a second channel 24, for instance for water outlet. Channels 23 and 24 have first and second open ends 27a and 27b, respectively, are located between two walls 25 and 26, here conventionally referred to as upper wall 25 and lower wall 26, and form a modular container for a liquid for thermal panel 21.

In accordance with the described embodiments, channels 23 and 24 have a predetermined height “h” and width “1”, and width “1” is much greater than height “h”.

For instance, height “h” may be in the range 5 to 7 mm, so that it allows reducing, in use, the overall weight of panel 10. Actually, as it can be readily understood, a reduction in height “h” results in a reduction of the volume of water circulating in the panel and hence in a reduction of the weight of the same panel when in use.

Therefore, reduction in height “h” is convenient to solve possible problems deriving from structural limits associated with panel positioning.

In the different embodiments, the first channel (inlet channel) 23 and the second channel (outlet channel) 24 are divided into two or three portions, of substantially the same or similar sizes, separated by respective columns 23a and 24a. Such configurations, which are deemed preferable, allow making basic frame 21 more rigid and less subject to deformations in case of compression stresses exerted, in use, by the water (e.g. 3-4 bars), in the exemplary case in which width “l” is much greater than height “h”.

Of course, in accordance with other embodiments, more than one or two columns can be provided, or the columns can be lacking, depending on the pressure envisaged, in use, in hybrid panel 10.

Moreover, basic frame 21 of each module 12 is configured so as to house in optimised manner photovoltaic panel 41 and protective component 43.

More particularly, basic frame 21 includes, on two opposite sides 31 and 32, conventionally referred to as first and second side edges, respectively, first and second C-shaped profiles 31a and 32a, respectively, which preferably are mutually specular and are configured for receiving photovoltaic cells 42 in an area adjacent to outer or upper face 25a and preferably separated from that face by a sheet 28, e.g. an electrically insulating but thermally conducting sheet, or a layer 28 with similar characteristics, of known type.

More preferably, an insulating layer 41b, e.g. a layer of EVA (Ethyl Vinyl Acetate), arranged to electrically insulate cells 42 from insulating sheet 28, is also interposed between insulating sheet 28 and cells 42.

In the alternative, in accordance with other embodiments, a transparent resin can be interposed between photovoltaic cells 42 and insulating sheet 28, as disclosed in patent publication WO2008/0044250 in the name of the Applicant.

Opposite edges 31 and 32 further include, besides C-shaped profiles and farther away from upper face 25a of basic frame 21, first and second L-shaped profiles 31b and 32b, respectively, arranged to receive protective component 43, for instance a glass pane, arranged to protect cells 42 of photovoltaic panel 41 for instance from atmospheric agents.

Preferably, an insulating layer 41a, e.g. a layer of EVA (Ethyl Vinyl Acetate) arranged to electrically insulate cells 42 from protective component 43, is interposed between protective component 43 and cells 42.

In the alternative, in accordance with other embodiments, a transparent resin can be interposed between protective component 43 and photovoltaic cells 42, as disclosed in patent publication WO2008/0044250_A1 in the name of the Applicant.

Preferably, one of the L-shaped profiles, e.g. the second L-shaped profile 32b, is extended, in a direction away from upper face 25a, by a hook-shaped element 32c shaped so as to protect cells 42 of photovoltaic panel 41 from possible seepage of water at the edges of protective component 43.

In accordance with a first embodiment of the present invention, side edges 31 and 32, respectively, further include coupling means 33 and 34, preferably located at a lateral position and externally of channels 23 and 24 and configured so as to mutually cooperate and to allow coupling panels 10 side by side.

For instance, coupling means 33 and 34 have a dovetail shape, female and male respectively, and are arranged to enable a longitudinal insertion of two basic frames into each other, as it can be readily understood by the skilled in the art, so as to allow building hybrid panels 10 with multiple modules 12 of predetermined length.

Basic frame 21 further includes, in correspondence of external or lower face 26a of lower wall 26, one or more seats or guides 36, for instance two seats, longitudinally arranged relative to basic frame 21 and arranged to house fastening means, for instance screw heads, at any position along the basic frame.

Thanks to such a configuration of the first embodiment, the screws allow fastening hybrid panel 10 to coupling bars or points external to the panel, the position of which is thus constrained in a single direction, as it can be readily understood by the skilled in the art.

In accordance with a second embodiment of the present invention, which is deemed preferable, side edges 31 and 32, respectively, are substantially flat, so that they can face each other.

Preferably, in such an embodiment, opposite fins 36a and 36b, respectively, extending over the whole length of basic frame 21, are provided in correspondence of retaining fins 35a and 35b.

Opposite or coupling fins 36a or 36b preferably allow achieving two objects:
a first object is, for instance, to allow coupling together, by means of removable coupling elements 46, for instance suitable pegs, hooks or clips, basic frames 21 of panels 10, so as to allow building hybrid panels 10 with multiple modules 12, for instance having a predetermined length and a width determined by the number of modules arranged side by side;
a second object is, for instance, making coupling fins 36a or 36b cooperate with retaining fins 35a and 35b, respectively, in order to form, near side edges 31 and 32, the seats or guides 36 arranged to house the fastening means, for instance screw heads, at any position along basic frame 21, of course except the points where pegs 46, if any, are provided.

As far as photovoltaic panel 41 is concerned, cells 42 are connected in series on each thermal panel 21, in known manner, so that connection terminals 42a and 42b, respectively, with opposite polarities are provided at the ends of inlet channel 23 and outlet channel 24.

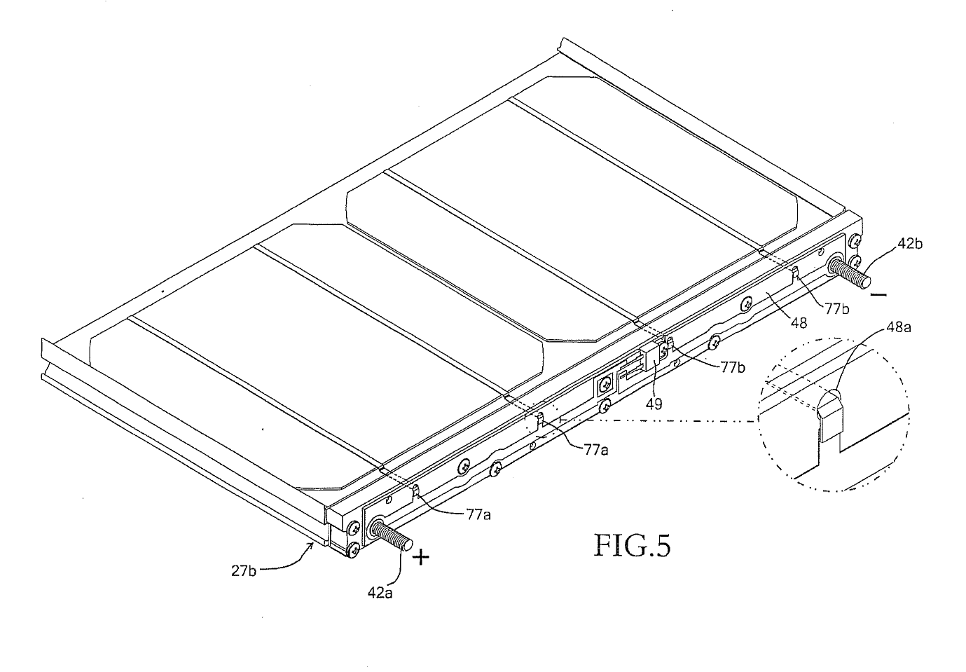

For instance, in the illustrated embodiment, the cells are arranged so that connection terminals 77a and 77b (FIG. 5), respectively, with opposite polarities are provided at the second ends 27b.

Preferably, the terminals are connected together by means of a hold or protective circuit 49, for instance a hold diode, known per se.

Preferably, the number of serially connected cells is 2 to 24, for instance in case of cells of known type having a size of 156×156 mm.

Hybrid panel 10 also comprises, preferably at both ends 27a and 27b (FIGS. 1a, 1b, 2a, 2b, 3, 4) of basic frame 21, a plurality of holes 37 for receiving screws 67, for instance self-threading screws.

Holes 37 are so arranged as to allow fastening first and second caps 39a and 39b, respectively, to the respective ends 27a and 27b of the basic frame, in order to enable completion of the manufacture of hybrid panel 10.

More particularly, the first cap 39a, in accordance with the present exemplary embodiment, is arranged to convey inflowing water towards inlet channel 23 and to convey water flowing out from outlet channel 24, for instance towards another module 12.

In accordance with a first embodiment shown in FIG. 1a, the first cap 39a is associated with an inlet hydraulic connector 59a and an outlet hydraulic connector 59b and it includes first and second cavities 53 and 54, respectively, not communicating with each other. The first cavity, or water inlet cavity 53, is arranged to convey water into inlet channel 23 and the second cavity 54 is arranged to convey water flowing out from outlet channel 24.

In accordance with a second embodiment shown in FIG. 1b, inlet and outlet hydraulic connectors 59a and 59b are included or formed in cap 39a.

Such a configuration, which is deemed preferable, allows making the hydraulic seal of the connectors safer and panel 10 more compact.

Preferably, the first cap is associated with one or more gaskets 38a, for instance one or more sealing gaskets made of silicone, arranged to ensure tightness of cap 39a by cooperating with screws 67.

In accordance with other embodiments, the gaskets could be replaced by a sealing material arranged to ensure tightness of the cap by cooperating with screws 67.

Gasket(s) 38a preferably has (have) one or more holes in correspondence with each cavity 53 and 54, respectively.

The holes, for instance two pairs of holes 53a, 53b and 54a, 54b, as illustrated in the first embodiment described herein, are arranged to make inlet water flow into the one or more portions into which inlet channel 23 is divided, and to make outlet water flow out from the one or more portions into which outlet channel 24 is divided.

More preferably, holes 53a and 54a have a smaller size than holes 53b and 54b in order to compensate, in use, possible pressure drops of the fluid inside cavities 53 and 54, respectively.

The second cap 39b includes, for instance, a first component 39b1, arranged to convey water from inlet channel 23 to outlet channel 24, a second component 39b2, arranged to take part in the electrical connection of cells 42 to connection terminals 42a and 42b, in order to supply with electric energy electrical devices, if any, connected to photovoltaic panel 41, and a third component 39b3, arranged to electrically insulate plate 48 and protective diode 49 from external agents and to seal panel 10 at the second end 27b.

In particular, in accordance with the different embodiments described herein, the first component 39b1 of cap 39b has a cavity 55 arranged to convey water from inlet channel 23 to outlet channel 24 of thermal panel 21.

Preferably, the first component 39b1 or cap 39b itself is associated with one or more gaskets 38b, for instance sealing gaskets made of silicone, arranged to ensure tightness of the first component 39b1 or of cap 39b by cooperating with screws 67.

In accordance with other embodiments, the gaskets could be replaced by a sealing material arranged to ensure tightness of cap 39b by cooperating with screws 67.

The second component 39b2 of cap 39b (FIG. 5) preferably includes a printed circuit board (circuit) with connection tracks and protective diode 49.

More preferably, circuit 48 has through-holes 48a, suitably electrically insulated and arranged to allow connecting terminals 77a and 77b of cells 42 to circuit 48, e.g. by bending terminals 77a and 77b and welding them to circuit 48.

The third component 39b3 of cap 39b, in the preferred embodiment of the invention, is to provide the overall protection of hybrid panel 10 at the second end 27b thereof.

Advantageously, in the preferred embodiment, the structure of second cap 39b, as illustrated herein, allows containing outside each module 12 both the hydraulic circuitry for connection between channels 23 and 24, and the electrical circuitry for connection among cells 42, thereby making maintenance of each module easier.

Of course, in accordance with other embodiments, the first and second caps may include the described components with a different arrangement, or they can be differently arranged, without thereby departing from the scope of what described and claimed.

The manufacture of a hybrid panel 10 in accordance with the present invention includes one or more of the following steps:
obtaining by an extrusion process one or more basic frames 21 of predetermined length, e.g. 6.5 m;
cutting basic frames 21 to the desired size, if necessary, depending on the kind of hybrid panel 10 to be manufactured, for instance depending on the number of photovoltaic cells to be installed, the solar power to be converted, and so on;
placing cells 42 on upper face 25a after having applied, for instance, layer 28 of an electrically insulating but thermally conducting material; such a step can be integrated with the deposition of an EVA layer;
placing protective panel 43, made for instance of glass, by exploiting L-shaped profiles 31b and 32b of the basic frame; such a step can be integrated with the deposition of an EVA layer;
applying thermally insulating panel(s) 45 to lower face 46a of basic frame 21, for instance by exploiting retaining fins 35a and 35b;
possibly arranging several basic frames 21 side by side, by exploiting, in accordance with the first embodiment, coupling means 33 and 34 of basic frame 21, or, in the alternative, in accordance with the second embodiment, by applying pegs 46, thereby forming hybrid panels 10 with multiple modules 12;
securing caps 39a and 39b having respective ducts and electric terminals to the panel.

Panel 10 manufactured in this manner has, thanks to basic frame 21, a self-supporting structure, which is easy to be handled and secured, for instance, to roofs or building structures.

In particular panel 10, thanks to the provision of guides 36, can be placed in flexible and handy manner on building roofs.

The panel, when associated with thermally insulating panels 45 applied on lower face 26a of basic frame 21, can also form building roofings.

Panel 10, having a basic frame or thermal panel 21 obtained by an extrusion process, is particularly rigid and thus such that it can prevent damages to cells 42 secured to the upper face of the basic frame.

The provision of caps 39a and 39b allows tightly sealing the panels and hydraulically connecting multiple modules.

More particularly, cap 39b also allows bringing protective circuit 49 outside the photovoltaic panel, allowing maintenance of the circuit without need to remove the photovoltaic panel.

Hybrid panels 10 as described may have a length and comprise a number of modules arranged side by side substantially depending only on the kind of installation to be made, in terms of surface to be covered and power to be delivered.

Hybrid panels 10 according to the invention are modular panels and are easy to be manufactured, in that they have a constant shape, possibly with variable length, so that standardised equipment can be used for their manufacture.

Moreover, in case of a failure in a panel with several modules 12, the constructional modularity allows replacing the failed module only, without need to replace the whole panel.

Such a feature makes it possible to provide kits of panels of standardised length, to be sold for performing a modular maintenance on the assembled panels.

Of course, obvious changes and/or modifications can be made in the above description in respect of the size, the shape, the components, the circuit elements and the connections, as well as in respect of the details of the illustrated construction and the manufacturing method, without departing from the scope of the invention as set forth in the following claims.

1. Solar panel structure comprising a basic frame arranged to constitute a thermal solar panel that can be combined with a photovoltaic solar panel having a plurality of cells, wherein
said basic frame is an extruded piece of predetermined length comprising at least one first channel arranged for inletting a liquid and one second channel arranged for outletting the liquid.

2. Structure according to claim 1, wherein:
said first and said second channel are comprised between a pair of sidewalls having a certain height, and an upper wall and a lower wall having a width much larger than the height of said pair of sidewalls; and
between each pair of sidewalls at least one column is provided connected to the upper and lower walls and arranged for giving rigidity to the thermal panel.

3. Structure according to claim 2, wherein one of the two walls comprises, on an external face of the basic frame, at least one guide arranged longitudinally to the structure and shaped so as to house fastening means in any position along the frame.

4. Structure according to claim 1, that constitutes a module having:
first coupling means located on a first side of said module; and
second coupling means located on a second side of said module;
said first coupling means and said second coupling means having a complementary shape so as to allow the frame to be connectable side by side to further modules.

5. Structure according to claim 1, that constitutes a module having:
first coupling means located on a first side of said module; and
second coupling means located on a second side of said module;
said first coupling means and said second coupling means being arranged to be coupled by removable coupling elements.

6. Hybrid solar panel comprising:
at least one basic frame arranged to constitute a thermal solar panel;
at least one photovoltaic solar panel having a plurality of cells fastened to a face of the basic frame;
wherein said basic frame, of predetermined length, is obtained by an extrusion process, comprises at least one first channel for inletting a liquid and at least one second channel for outletting the liquid, and is arranged to constitute, combined with said photovoltaic panel, a hybrid solar panel of modular type.

7. Hybrid solar panel according to claim 6, wherein said basic frame comprises on a first side and on a second side, respectively:
a first C-shaped profile and a second profile specular to the first one, arranged to house said photovoltaic solar panel; and
a first L-shaped profile and a second profile specular to the first one, arranged to house a protective component of said photovoltaic solar panel.

8. Hybrid solar panel according to claim 6, wherein said basic frame comprises on a first side and on a second side, respectively:
first coupling means and second coupling means having a complementary shape so as to allow the panel to be connectable side by side to further hybrid solar panels of modular type.

9. Hybrid solar panel according to claim 6, wherein said basic frame comprises on a first side and on a second side, respectively:
first coupling means and second coupling means arranged to be coupled by removable coupling elements.

10. Hybrid solar panel according to claim 6, further comprising, on opposite ends of the basic frame:
respective caps arranged to seal the panel of modular type and at least to convey the inlet and outlet liquid.

11. Method of manufacturing a hybrid solar panel, comprising the steps of
making a basic frame arranged to constitute a thermal solar panel;
fastening to the basic frame a photovoltaic solar panel comprising a plurality of cells;
wherein said step of making a thermal solar panel comprises the step of:
obtaining through an extrusion process a basic modular frame of predetermined length.

12. Method according to claim 11, wherein said step of making a thermal solar panel comprises the further step of:
applying to opposite ends of the basic frame, obtained through the extrusion process, caps arranged to seal the panel and at least to convey the inlet and outlet liquid.

13. Repair kit for hybrid solar panel, comprising:
a hybrid modular panel having a basic frame comprising:
first coupling means located on a first side of said modular panel; and
second coupling means located on a second side of said modular panel;
said first coupling means and said second coupling means having a complementary shape so as to allow the modular panel to replace a failed hybrid solar panel and to be connectable side by side to further modules.

14. Repair kit for hybrid solar panel, comprising:
a hybrid modular panel having a basic frame comprising:
first coupling means located on a first side of said modular panel; and
second coupling means located on a second side of said modular panel;
said first coupling means and said second coupling means being arranged to be coupled by removable coupling elements, so as to allow the modular panel to replace a failed hybrid solar panel and to be connectable side by side to further modules.
